(19) United States
(12) Patent Application Publication
(10) Pub. No.: US 2025/0266631 A1
(43) Pub. Date: Aug. 21, 2025

(54) Printed Circuit Board having at Least One Contact Element, a Housing having Such a Printed Circuit Board and a Method for Completing a Low Resistance Electrical Connection

(71) Applicant: Robert Bosch GmbH, Stuttgart (DE)

(72) Inventor: Friedrich Braun, Boebingen (DE)

(21) Appl. No.: 19/049,718

(22) Filed: Feb. 10, 2025

(30) Foreign Application Priority Data
Feb. 15, 2024 (DE) 10 2024 201 384.6

(51) Int. Cl. H01R 12/82; H01R 12/75; H01R 13/24; H05K 5/02; H05K 5/04

(52) U.S. Cl. CPC H01R 12/82; H01R 12/75; H01R 13/2478; H05K 5/0247; H05K 5/04

(57) ABSTRACT

A printed circuit board having at least one contact element is disclosed. A fixed end of the contact element is connected to the printed circuit board and a free end of the contact element includes a contact point for contacting an oxidized contact surface. An S-shaped spring region is disposed between the fixed end and the free end, defining a direction of compression of the contact point substantially perpendicular to a main extension plane of the printed circuit board. The contact point includes at least one sharp edge for penetrating an oxide layer of the contact surface. Flanks of the sharp edge are oriented oblique to the compression direction.

This application claims priority under 35 U.S.C. § 119 to patent application no. DE 10 2024 201 384.6, filed on Feb. 15, 2024 in Germany, the disclosure of which is incorporated herein by reference in its entirety.

The disclosure relates to a printed circuit board having at least one contact element, a housing having such a printed circuit board, and a method for completing a low resistance electrical connection.

### BACKGROUND

To connect a printed circuit board with an electrical potential of a metal housing, the printed circuit board may comprise a cable having a plug contact. A corresponding plug contact can be disposed on the housing. During assembly, the plug contacts are connected, the printed circuit board is connected to a housing component and the housing is closed by a further housing component. Alternatively, the printed circuit board may comprise a soldered spring contact element having a domed or spherical contact area to the housing.

### SUMMARY

In light of this, with the approach presented herein, a printed circuit board having at least one contact element, a housing having such a printed circuit board, and a method for completing a low resistance electrical connection are presented. Advantageous further developments and improvements of the approach presented here will emerge from the description and are presented below.

A metal housing may be made of a metallic material that forms an oxide layer with poor electrical conductivity. The metallic material may be, for example, an aluminum material. Thus, contacting the housing for the purpose of electrical potential equalization is difficult. At present, therefore, a contact element made of a metallic material that does not form or that forms only small oxide layers is disposed on the housing. This contact element is then contacted by a matching contact element of a printed circuit board. The contact element of the printed circuit board can in particular be disposed on a cable. Alternatively, the contact element may be a spring contact with a spherical dome-shaped contact point soldered on the printed circuit board. For example, the contact element may be gold plated.

In the approach presented here, a contact element is fixedly arranged on the printed circuit board. The housing merely comprises a contact surface made of the metallic material of the housing. The contact surface may be covered by an oxide layer. The contact element comprises at least one non-deburred or sharp edge at a contact point for contacting the contact surface. The edge penetrates the oxide layer of the housing material and reaches non-oxidized metallic material. This results in an electrically conductive connection between the printed circuit board and the housing, which has a low transition resistance.

By the approach presented here, an extra plug connection for equipotential bonding or a separate contact surface made of a non-oxidizing material or a low oxidizing material can be omitted. This simplifies the mounting of the printed circuit board in the housing.

According to a first aspect of the disclosure, a printed circuit board with at least one contact element is presented, wherein a fixed end of the contact element is connected to the printed circuit board and a free end of the contact element comprises a contact point for contacting an oxidized contact surface, wherein an S-shaped spring region is arranged between the fixed end and the free end, defining a compression direction of the contact point substantially perpendicular to a main extension plane of the printed circuit board, wherein the contact point comprises at least one sharp edge for penetrating an oxide layer of the contact surface, wherein flanks of the sharp edge are oriented oblique to the compression direction.

According to a second aspect of the disclosure, a housing having at least one inserted printed circuit board according to the first aspect is presented, wherein the contact point abuts an oxidized contact surface of the housing and the spring area is compressed in the compression direction, wherein the sharp edge is pressed against the contact surface with a resulting pressing force, penetrating an oxide layer of the contact surface and completing a low resistance electrical connection between the printed circuit board and the contact surface.

According to a third aspect of the disclosure, a method is presented for completing a low resistance electrical connection between a printed circuit board according to the first aspect and a housing, wherein the sharp edge is placed on an oxidized contact surface of the housing and the spring area is compressed in the compression direction, wherein the sharp edge is pressed against the contact surface with a resulting pressing force, wherein the sharp edge penetrates the oxide layer and completes the low resistance electrical connection to the non-oxidized material of the contact surface.

Ideas concerning embodiments of the present disclosure may be regarded as being based, among other things, on the thoughts and findings described below.

A contact element may be composed of an electrically conductive metallic material. For example, the contact element may be a stamped bent part. A sharp edge may be produced by not deburring a cut edge of the contact element. Alternatively, the cut edge may be subsequently sharpened. The sharp edge results in a high surface compression when the edge contacts a contact surface of a contact partner. The surface compression may be so high that the sharp edge at least partially penetrates into the contact surface. Upon intrusion, an oxide layer on the contact surface is destroyed and non-oxidized material under the oxide layer is exposed. The sharp edge may penetrate the contact surface particularly well when the sharp edge is moved relative to the contact surface upon placement on the contact surface.

The contact partner may in particular be a housing made of an oxidizing material.

The sharp edge may be disposed at a free end of the contact element. The free end may be provided as a contact point of the contact element. In this way, the contact element can be elastically deformed when the contact point touches the contact surface of the contact partner. Thus, the contact element may compensate for manufacturing tolerances and/or assembly tolerances.

At an opposite end, the contact element may comprise a fastening region for fastening to a printed circuit board. The fastening region can in particular be configured to be soldered to the printed circuit board.

A spring region may be disposed between the contact point and a fastening region for fastening to the printed circuit board. The spring region may be bent transverse to a spring direction of the spring region. The spring region may reduce a stiffness of the contact element in the spring direction. The stiffness may be increased transversely to the spring direction by the spring region. The pressing force of the sharp-edged region can be adjusted to the contact surface by the spring region.

The spring region may be S-shaped. The spring region may be curved twice in opposite directions. The S-shape may reduce a bending load per bending point. The contact element may be compact in design due to the S-shape.

The pressing force of the spring in conjunction with the sharp edge may be capable of establishing a gas-tight connection between the contact area of the spring and the housing. Re-oxidation by the oxygen contained in the air may thus be prevented.

The sharp edge may extend around a protruding tip of the contact element. The sharp edge may form a tip. The tip may penetrate the oxide layer even at a low pressing force.

The sharp edge may extend along a curved protrusion of the contact element. The sharp edge may form a blade. The blade may be convex. Thus, a partial area of the blade may always abut the contact surface, even if an angle between the contact element and the contact surface changes.

The tip or protrusion may be oblique to the main extension plane of the printed circuit board. A distance between the spring region and the contact surface may be increased by an oblique position.

The sharp edge may be aligned in a direction of insertion of the contact element. In particular, when the sharp edge forms a blade, the sharp edge may be moved along the edge over the contact surface as the contact element is placed on the contact surface. The printed circuit board may be inserted into a receptacle of the housing. The contact element may be placed on the contact surface and moved over the contact surface in the insertion direction of the printed circuit board.

The contact element may have two sharp edges. The edges may be disposed on opposite sides of the contact point. The contact element may complete an electrical contact to the contact surface at two locations through the two sharp edges. Two sharp edges may reduce a tilting of the contact point on the contact surface. Even if one sharp edge is damaged, the other sharp edge may ensure electrical contacting.

It should be noted that some of the possible features and advantages of the disclosure are described here with reference to different embodiments. A person skilled in the art will recognize that the features of the control device and the method can be suitably combined, adapted, or interchanged to arrive at further embodiments of the disclosure.

### BRIEF DESCRIPTION OF THE DRAWINGS

Embodiments of the disclosure are described in the following with reference to the accompanying drawings, wherein neither the drawings nor the description are to be construed as limiting the disclosure.

FIGS. 1-5 show representations of contact points of contact elements according to exemplary embodiments.

The figures are merely schematic and are not to scale. Identical reference numerals denote identical or functionally identical features.

### DETAILED DESCRIPTION

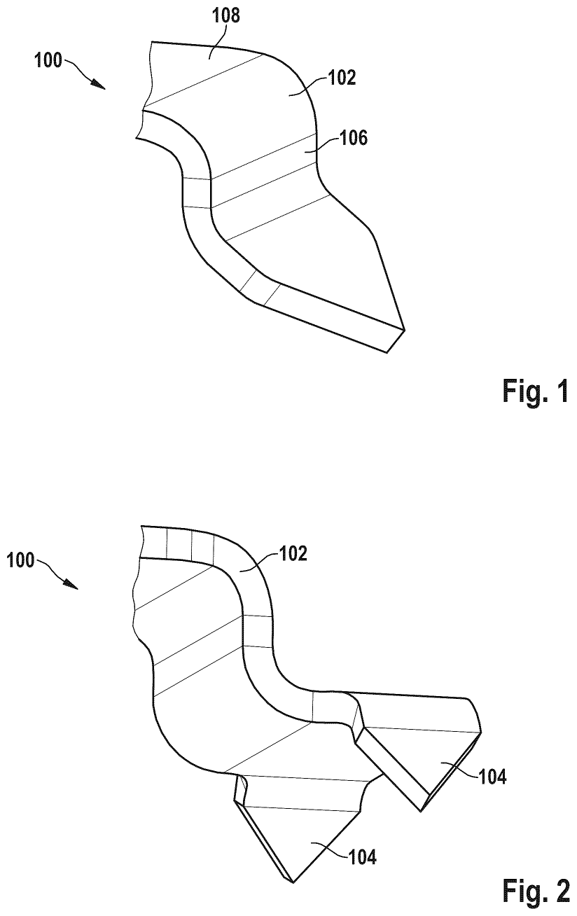

FIG. 1 shows a diagram of a contact point 100 of a contact element 102 in accordance with an exemplary embodiment. The contact point 100 is disposed on a free end of the contact element 102. At a fixed end not shown here, the contact element 102 is connected to a printed circuit board. The contact element 102 is configured to establish a low-resistance electrically conductive connection, i.e. an electrically conductive connection with a very low contact transition resistance, between the printed circuit board and a metal housing with an electrically insulating oxide layer as the potential contact.

The contact element 102 is a stamped bent part made of sheet metal. The contact point 100 is configured as a flat tip or claw. The tip faces in a main direction of extension of the contact element 102. At least at the contact point 100, the contact element 102 has a sharp edge 104. The sharp edge 104 is disposed on both sides of the tip and runs across the tip. The sharp edge 104 is a non-deburred cutting edge of the stamped bent part.

When the contact point 100 is placed on a contact surface of the housing, the sharp edge 104 first touches the contact surface. The sharp-edged tip exerts a pressing force with which the contact element 102 is pressed against the contact surface over a very small area, whereby a high area pressure results even from a low pressing force. Due to the high area pressure, the sharp edge 104 or the tip penetrates the electrically insulating oxide layer, which is very likely present on the contact surface, even at a low pressing force and thus ensures the low-resistance electrical connection between the contact element 102 and the housing.

In an exemplary embodiment, the contact point 100 is obliquely bent out of a main extension plane of the contact element 102 towards the contact surface. Here, for example, the flat tip is oriented 45° oblique to the main extension plane. As a result, the sharp edge 104 protrudes towards the contact surface. This prevents another area of the contact element 102 from coming into contact with the contact surface and reduces the pressing force on the sharp edge 104.

In an exemplary embodiment, the contact point 100 is designed to be offset by a step 106 from the main extension plane. Due to the step 106, the sharp edge 104 projects from the contact element 102 towards the contact surface. This prevents another area of the contact element 102 from coming into contact with the contact surface and reduces the pressing force on the sharp edge 104.

The contact element 102 has a spring region 108 between the contact point 100 and the attachment location. The spring region 108 is elastic and is elastically deformed upon contacting the contact point 100, thereby pressing the contact point 100 against the contact surface with the pressing force resulting from a return force due to the elastic deformation. Due to the spring region 108, the contact element 102 is able to compensate for shape and position tolerances between the printed circuit board and the housing.

The spring region 108 is curved in an S-shape here. As a result, the spring region 108 has a reduced spring stiffness and may provide an approximately constant pressing force over a larger area of deformation. In addition, the entire contact element 102 is very compact due to the doubly curved spring region 108.

In one exemplary embodiment, the contact element 102 is nickel coated. This results in a low electrochemical voltage difference between the contact point 100 and the contact surface. Thus, if there is moisture at the contact point 100, electrochemical corrosion can be minimized and the low resistance electrical connection can be permanently ensured.

FIG. 2 shows a diagram of a contact point 100 of a contact element 102 in accordance with an exemplary embodiment. The contact point 100 substantially corresponds to the contact point in FIG. 1. In contrast, the contact point 100 has two sharp edges 104 each configured as a tip. The tips here face transversely to the main extension direction of the contact element 102. The tips face in opposite directions. The two sharp edges 104 break open the oxide layer of the contact surface at two locations and ensure the low resistance connection at least at one of the tips if one of the tips should have an increased contact transition resistance.

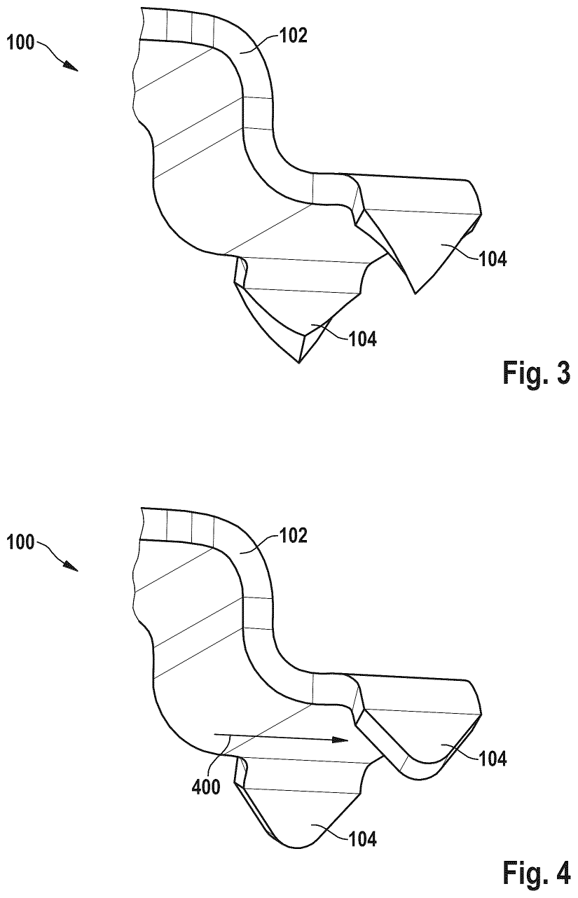

FIG. 3 shows a diagram of a contact point 100 of a contact element 102 in accordance with an exemplary embodiment. The contact point 100 substantially corresponds to the contact point in FIG. 2. In contrast, the two tips are designed here to be angled by more than 90° relative to the main extension plane. As such, the tips below the contact point 100 and the sharp-edged areas 104 are arranged closer together than in FIG. 2.

FIG. 4 shows a diagram of a contact point 100 of a contact element 102 in accordance with an exemplary embodiment. The contact point 100 substantially corresponds to the contact point in FIG. 2. In contrast, the sharp edges 104 are disposed here on curved protrusions of the contact point 100. The protrusions are arranged transverse to the main extension direction as in FIG. 2 and oblique to the contact surface. This allows the contact points to slide on the contact surface of the housing along the extension direction of the contact spring with a low risk of chipping. Due to the curved shape, a partial area of the sharp edge is always tangentially aligned with the contact surface at different angles between the contact element 102 and the contact surface. Thus, the sharp edges 104 can penetrate particularly efficiently through the oxide layer and establish the low resistance contact.

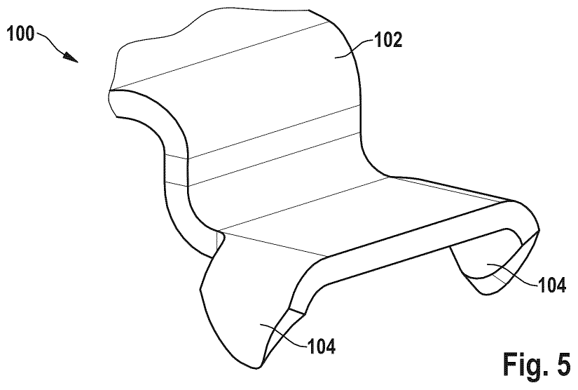

FIG. 5 shows a diagram of a contact point 100 of a contact element 102 in accordance with an exemplary embodiment. The contact point 100 substantially corresponds to the contact point in FIG. 4. In contrast, the two protrusions are designed here to be angled by more than 90° relative to the main extension plane. Thus, the protrusions below the contact point 100 and the sharp edges 104 are disposed closer together than in FIG. 4.

Possible embodiments of the disclosure are summarized again below or presented with a slightly different choice of words.

A contact element design for penetration of metal oxide layers and a completion of a reliable low resistance electrical connection is presented.

By the approach presented herein, electrical contacting of metals forming electrically non-conductive metal oxide layers, e.g. aluminum, can be carried out safely.

An EPS may have high interference emissions. The ECU may be completely enclosed by an aluminum enclosure and may require a low-resistance electrical connection between the metal housing and the printed circuit boards. If the contact transition resistances are significantly higher than specified, the EMC filter efficiency may be too low. As a result, the EMC interference emissions may be significantly out of specification.

Elastic electrical contacting of electrical assemblies to a complete or partial metal housing around the electronic assemblies is realized by spring elements fixed to printed circuit boards. The purpose of these spring elements is to establish a low-resistance electrical connection between a metal housing component and an electrical potential of an electronic assembly, e.g. a printed circuit board.

Typically, the contact points of spring elements have a dome or spherical-shaped geometry towards the metal housing parts to be contacted. Such geometry is suitable for establishing a low-resistance electrical connection with highly electrically conductive surfaces of contact partners.

However, if the metals of the contact partners form poor or non-conductive (insulative) surfaces, a domed or spherical contact point geometry is not suitable. Aluminum or aluminum alloys, for example, form poor or non-conductive surfaces due to the formation of aluminum oxides. A dome or spherical contact geometry may have a difficult time penetrating such an oxide layer and establishing a reliable contact.

Elastic contacting elements available on the market with their domed or spherical contact point geometry are not suitable for producing a reliable and low resistance electrical connection between the metal housings used in the EPS, which are for instance made of aluminum or aluminum alloys and, for instance printed circuit boards without an additional surface treatment such as passivation. The contact geometry is not capable of reliably penetrating an insulating oxide layer with the contact force typically present and completing a safe and low resistance electrical connection. However, such a connection is of elementary importance for the efficacy and efficiency of EMC filter assemblies in the EPS.

A further problem, in particular of S-shaped or double S-shaped spring geometries, is that when the spring element is compressed, the contact point “wanders” in the plane of the contact surface of the contact partner. This movement of the contact point leads to scraping of the natural oxide layer of the aluminum component in the case of spherical or dome-shaped contact geometry and corresponding pressing force. However, the removed oxide may push in as a wedge between the contact dome and the contact surface. The electrical transition resistance is unstable and may increase significantly.

To ensure efficient filtering by the EMC filters, a contact transition resistance of less than 160 m′ for (3γ) or less than 200 m′ for (6′) is advantageous. The available contact spring designs do not meet this requirement. Therefore, an optimized design is urgently needed.

The approach presented herein allows the filter efficiency of EMC filter elements to be increased significantly due to lower contacting or transition resistances. EMC emissions can be reduced by over 20 dB by the approach presented herein, which corresponds to a factor of 0.1. EMC requirements can be met without large and heavy inductive EMC filter components and by utilizing fewer or smaller filter elements.

The contact geometry presented herein makes it possible to realize a very low resistance contact transition resistance between a contact spring and a metal surface with a natural insulating oxide layer. The contact geometry is capable of penetrating a natural metal oxide layer due to high point contact forces. The contact geometry prevents metal oxides that are not conductive or that are poorly electrically conductive from building up between the contact surfaces upon displacement of the contact point between the contact partners, thereby increasing and/or causing an instability of the contact transition resistance.

An alternative contact area geometry for electrical contacting elements is presented, which allows for significantly higher contact pressures (force by surface area) with the same spring force, and thus allows for easier penetration of insulating oxide layers on metals with simultaneously reduced contact resistance. The contact area geometry further reduces the buildup of insulating metal oxides between the spring contact geometry and the contact surface in certain shapes of contact geometry and when the contact point slides over the contact surface to the extent that there is no adverse impact on the contact transition resistance. In certain contact geometry shapes, sliding of the contact point and a buildup of insulating oxides between the contact element and contact surface is avoided. In certain contact geometry shapes, a deep intrusion of the contact geometry into the metal to be contacted is allowed while the oxide layers are displaced, thereby allowing a gas-tight, electrically low-impedance connection that prevents oxidation of the contact point of an aluminum material by oxygen in the air. Certain contact geometry shapes will largely avoid chip formation when the contact point slides over the contact surface. The contact area geometry allows for a significantly lower electrical contact-transition resistance with the contact forces present. The contact area geometry allows for a significantly lower variance of the contact transition resistance with the contact forces present.

The surface coating of the contact geometry is selected so that the electromechanical voltage difference to the material to be contacted is minimized. This minimizes electrochemical corrosion of the base material under the influence of moisture. The coating has a high surface conductivity. For example, a nickel coating is used. A gold coating is not an advantage due to the high electrical voltage difference upon contacting aluminum materials.

Instead of the typically used dome or spherical contact point geometry, alternative geometries are used here. The contacting of oxide-forming (electrically insulating) metallic surfaces is carried out by geometries in the form of edges (including curved edges) or tips, which are capable, if a suitable hardness is chosen for the contacting element, of penetrating a metal oxide layer and producing a low-resistance and reliable electrical contact, wherein when the contact areas of the spring penetrate into the aluminum material to be contacted, a gas-tight connection is formed which prevents oxide formation in the area of the contact point as far as possible by oxygen in the ai.

An exemplary embodiment of the contact geometry allows for a high surface compression in the contact area and thus the penetration of an insulating metal oxide layer by the use of an edge as the contact geometry, embodied as an arc. If the contact point slides, an accumulation of insulating oxide between the contact geometry and contact surface is minimized so that no negative effects are produced on the contact transition resistance. A double point of contact increases contact reliability. Alternatively, a design with only one angled contact area is also possible.

In one exemplary embodiment, the two contact points are arranged closer to each other. Alternatively, a design with only one angled contact area is also possible.

In one exemplary embodiment, an even higher area pressure point is achieved in the contact area. Oxide layers are more readily penetrated and the contact geometry also makes electrical contact to the metallic contact partner with thicker oxide layers, allowing for very low transition resistances. Displacement of the contact point is in particular avoided with S or double S-shaped spring elements. This also reduces the effect of the accumulation of oxides under the contact. Alternatively, a design with only one angled contact area is also possible.

One exemplary embodiment has fewer bending operations and is easier to manufacture.

The contact geometry of the spring element has been remachined so that an edge is formed as the point of contact instead of a dome. Measurements all show results within the specification and with a significant distance from the limit.

Lastly, it should be noted that terms such as “comprising”, “including”, etc. do not exclude other elements or steps and terms such as “one” or “a” do not exclude a plurality. Reference numerals in the claims should not be construed as limitations.

What is claimed is:

1. A printed circuit board comprising at least one contact element, wherein:
a fixed end of the contact element is connected to the printed circuit board and a free end of the contact element includes a contact point configured to contact an oxidized contact surface,
an S-shaped spring region is disposed between the fixed end and the free end, defining a direction of compression of the contact point which is substantially perpendicular to a main extension plane of the printed circuit board,
the contact point includes at least one sharp edge configured to penetrate an oxide layer of the contact surface, and
flanks of the sharp edge are oriented oblique to the compression direction.

2. The printed circuit board according to claim 1, wherein the sharp edge extends around a protruding tip of the contact point.

3. The printed circuit board according to claim 1, wherein the sharp edge is configured to run along a curved protrusion of the contact point.

4. The printed circuit board according to claim 2, wherein the protruding tip is oriented oblique to the main extension plane of the printed circuit board.

5. The printed circuit board according to claim 1, wherein:
the contact element is embodied as a stamped bent part, and
the sharp edge is formed by a non-deburred edge of the stamped bent part.

6. The printed circuit board according to claim 1, wherein the sharp edge is aligned in a housing in an insertion direction of the printed circuit board.

7. The printed circuit board according to claim 1, wherein:
the at least one sharp edge includes a first sharp edge and a second sharp edge, and
the first sharp edge and the second sharp edge are arranged on opposite sides of the contact point.

8. A housing comprising at least one printed circuit board according to claim 1, wherein:
the contact point abuts an oxidized contact surface of the housing and the spring region is compressed in the spring direction, and
the sharp edge is pressed against the contact surface with a resulting pressing force so as to penetrate an oxide layer of the contact surface and complete a low resistance electrical connection between the printed circuit board and the contact surface.

9. A method for completing a low resistance electrical connection between (i) a housing, and (ii) the printed circuit board according to claim 1, comprising:
placing the sharp edge on an oxidized contact surface of the housing and compressing the spring region in the spring direction;
pressing the sharp edge against the contact surface with a resulting pressing force; and
penetrating the oxide layer with the sharp edge and completing the low resistance electrical connection to the non-oxidized material of the contact surface.

10. The printed circuit board according to claim 3, wherein the curved protrusion is oriented oblique to the main extension plane of the printed circuit board.
